(19) United States
(12) Patent Application Publication
(10) Pub. No.: US 2010/0072623 A1
(43) Pub. Date: Mar. 25, 2010

(54) SEMICONDUCTOR DEVICE WITH IMPROVED CONTACT PLUGS, AND RELATED FABRICATION METHODS

(75) Inventors: Christopher M. PRINDLE, Poughkeepsie, NY (US); Richard J. CARTER, Hopewell Junction, NY (US); Doug LEE, Poughquag, NY (US); Man Fai NG, Poughkeepsie, NY (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 12/233,832

(22) Filed: Sep. 19, 2008

(51) Int. Cl. H01L 21/768; H01L 23/532

(52) U.S. Cl. 257/763; 438/656; 257/E21.585; 257/E23.163

(57) ABSTRACT

Semiconductor device structures and related fabrication methods are provided herein. One fabrication method relates to the formation of conductive contact plugs for a semiconductor device. The method begins by providing a semiconductor device structure having a conductive contact region, a layer of insulating material overlying the conductive contact region, and a via formed in the layer of insulating material and terminating at the conductive contact region. The fabrication process then deposits a first electrically conductive material on the semiconductor device structure such that the first electrically conductive material at least partially fills the via. Then, the process anisotropically etches a portion of the first electrically conductive material located in the filled via, resulting in a lined via. Thereafter, the process deposits a second electrically conductive material on the semiconductor device structure such that the second electrically conductive material at least partially fills the lined via.

### TECHNICAL FIELD

Embodiments of the subject matter described herein relate generally to semiconductor devices. More particularly, embodiments of the subject matter relate to the fabrication of conductive contact plugs suitable for use with semiconductor devices.

### BACKGROUND

The majority of present day integrated circuits (ICs) are implemented by using a plurality of interconnected field effect transistors (FETs), which may be realized as metal oxide semiconductor field effect transistors (MOSFETs or MOS transistors). A MOS transistor may be realized as a p-type device (i.e., a PMOS transistor) or an n-type device (i.e., an NMOS transistor). Moreover, a semiconductor device can include both PMOS and NMOS transistors, and such a device is commonly referred to as a complementary MOS or CMOS device. A MOS transistor includes a gate electrode as a control electrode that is formed over a semiconductor substrate, and spaced-apart source and drain regions formed within the semiconductor substrate and between which a current can flow. The source and drain regions are typically accessed via respective conductive contacts formed on the source and drain regions. Bias voltages applied to the gate electrode, the source contact, and the drain contact control the flow of current through a channel in the semiconductor substrate between the source and drain regions beneath the gate electrode. Conductive metal interconnects (plugs) formed in an insulating layer are typically used to deliver bias voltages to the gate, source, and drain contacts.

Modem semiconductor device fabrication processes utilize tungsten to form the conductive contact plugs. The tungsten is usually deposited by way of chemical vapor deposition (CVD). Unfortunately, the columnar formation of tungsten during the CVD process can result in a void within the center of the conductive contact plug (this void is sometimes referred to as a “seam” or a “keyhole” or a “pocket”). Voids in conductive contact plugs increase the contact resistance of the device, which in turn can degrade the performance of the device. Although such voids may be tolerable when using larger scale process node technologies, they can be more problematic when using smaller scale process node technologies (e.g., 45 nm and below), due to the increased aspect ratio of the conductive contact plugs. In other words, a void in a conductive contact plug having a relatively large diameter (or cross sectional area) will not affect the contact resistance as much as a void in a conductive contact plug having a relatively small diameter (or cross sectional area).

### BRIEF SUMMARY

A semiconductor device, such as a transistor device, includes at least one conductive contact plug that is formed in accordance with the techniques described herein. More particularly, the conductive contact plugs are fabricated such that voids are eliminated or substantially reduced in size. A method of forming conductive contact plugs for a semiconductor device is provided. The method begins by providing a semiconductor device structure having a conductive contact region, a layer of insulating material overlying the conductive contact region, and a via formed in the layer of insulating material and terminating at the conductive contact region. The method involves depositing a first electrically conductive material on the semiconductor device structure such that the first electrically conductive material at least partially fills the via, resulting in a filled via, anisotropically etching a portion of the first electrically conductive material located in the filled via, resulting in a lined via, and thereafter depositing a second electrically conductive material on the semiconductor device structure such that the second electrically conductive material at least partially fills the lined via.

The above and other aspects may be found in an embodiment of a semiconductor device. The semiconductor device includes: a semiconductor material; a conductive contact region for the semiconductor material; a layer of insulating material overlying the semiconductor material and the conductive contact region; and a conductive contact plug formed in the layer of insulating material and terminating at the conductive contact region. The conductive contact plug includes an etched liner formed from a first electrically conductive material, and a second electrically conductive material deposited in the etched liner.

Another method of forming conductive contact plugs for a semiconductor device is also provided. This method begins by providing a semiconductor device structure having a conductive contact region, a layer of insulating material overlying the conductive contact region, and a via formed in the layer of insulating material and terminating at the conductive contact region. The fabrication of the contact plugs involves the depositing of a metal material in the via such that the metal material partially fills the via, resulting in a partially filled via. Next, the method anisotropically etches a portion of the metal material located in the partially filled via, resulting in a lined via. Thereafter, the metal material is deposited in the lined via such that the metal material at least partially fills the lined via, resulting in a subsequently filled via. If the metal material does not substantially fill the subsequently filled via, the method deposits more of the metal material in the subsequently filled via.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a cross sectional view of a semiconductor device structure in a state following front end processing;

FIG. 2 is a cross sectional view of the semiconductor device structure, after formation of vias in a layer of insulating material; and

FIGS. 3-13 are cross sectional views that illustrate the formation of conductive contact plugs for the semiconductor device structure; and

FIG. 14 is a cross sectional view of the semiconductor device structure, after formation of the conductive contact plugs.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

For the sake of brevity, conventional techniques related to semiconductor device fabrication may not be described in detail herein. Moreover, the various tasks and process steps described herein may be incorporated into a more comprehensive procedure or process having additional steps or functionality not described in detail herein. In particular, various steps in the manufacture of semiconductor based transistors are well known and so, in the interest of brevity, many conventional steps will only be mentioned briefly herein or will be omitted entirely without providing the well known process details.

The techniques and technologies described herein may be utilized to fabricate conductive contact plugs for MOS transistor devices, including NMOS transistor devices, PMOS transistor devices, and CMOS transistor devices. Although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate.

FIG. 1 is a cross sectional view of a semiconductor device structure 100 in a state following front end processing. FIG. 1 depicts an intermediate state in the overall fabrication process after formation of device structure 100. Device structure 100 is formed using well known techniques and process steps (e.g., techniques and steps related to doping, photolithography and patterning, etching, material growth, material deposition, surface planarization, and the like), which will not be described in detail here.

Fabrication of device structure 100 may begin by providing a suitable substrate 102 having a layer of semiconductor material 104. In practice, substrate 102 may be realized as a silicon-on-insulator (SOI) substrate, where semiconductor material 104 is disposed on a layer of insulator material that, in turn, is supported by a carrier wafer (not shown). In alternate embodiments, device structure 100 can be formed on a bulk silicon substrate rather than an SOI substrate.

Although any suitable semiconductor material may be employed, for this embodiment semiconductor material 104 is a silicon material, where the term “silicon material” is used herein to encompass the generally monocrystalline and relatively pure silicon materials typically used in the semiconductor industry, as well as silicon admixed with other elements such as germanium, carbon, and the like. Alternatively, semiconductor material 104 can be germanium, gallium arsenide, or the like. Semiconductor material 104 can originally be either N-type or P-type silicon, but is typically P-type, and semiconductor material 104 is subsequently doped in an appropriate manner to form active regions. The active regions can be used for the source and drain regions 106 of the resulting transistor devices.

The substrate 102 is subjected to various process steps to form device structure 100 depicted in FIG. 1. For this simplified depiction, device structure 100 includes, without limitation: a gate structure 108 overlying semiconductor material 104; source/drain regions 106 formed in semiconductor material 104; conductive contact regions 110 for source/drain regions 106; a conductive contact region 111 for gate structure 108; and a layer of insulating material 112 overlying semiconductor material 104, gate structure 108, conductive contact regions 110, and conductive contact region 111.

Conductive contact regions 110/111 are typically realized as silicide contact areas, and conductive contact regions 110/111 can be formed using an appropriate silicidation process. For example, a layer of silicide-forming metal (not shown) is deposited onto exposed silicon surfaces corresponding to the source, drain, and gate areas. The silicide-forming metal can be deposited, for example, by sputtering to a thickness of about 5-50 nm and preferably to a thickness of about 10 nm. The device structure is then heated, for example by rapid thermal annealing, to form metal silicide areas corresponding to conductive contact regions 110/111. The silicide-forming metal can be, for example, cobalt, nickel, rhenium, ruthenium, or palladium, or alloys thereof. Any silicide-forming metal that is not in contact with exposed silicon does not react during heating and, therefore, does not form a silicide. This excess metal may be removed by wet etching or any suitable procedure.

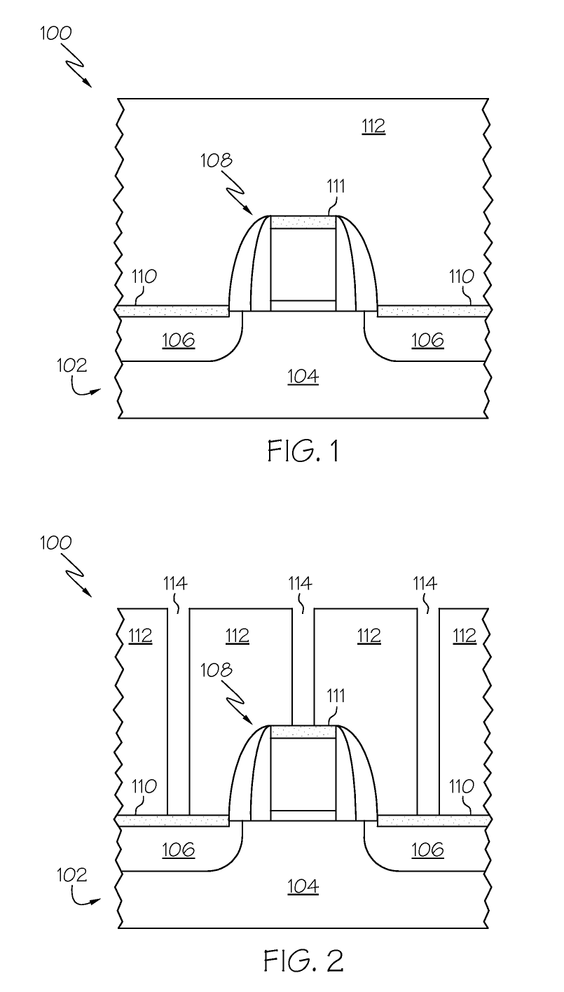

After conductive contact regions 110/111 have been created, the layer of insulating material 112 is formed over gate structure 108, over semiconductor material 104, and over conductive contact regions 110/111 (as depicted in FIG. 1). Insulating material 112 may be composed of one or more suitable dielectric materials, for example, an oxide material, nitride or other low-k materials, or the like. After deposition, the layer of insulating material 112 can be polished (planarized), patterned, and etched to define vias 114 above conductive contact regions 110/111. FIG. 2 is a cross sectional view of device structure 100 after formation of vias 114. As shown in FIG. 2, each via 114 terminates at a respective conductive contact region 110/111. For 45 nm node technology, vias have a typical diameter in the range of about 50-70 nm, and a typical height in the range of about 300-500 nm. These exemplary dimensions are not intended to limit the scope or application of the subject matter, and an embodiment of device structure 100 may utilize vias 114 having different dimensions.

After the device structure 100 depicted in FIG. 2 has been provided, the fabrication process continues by forming conductive contact plugs for the semiconductor device. In practice, substrate 102 may include thousands (or more) of semiconductor device structures, and thousands (or more) of vias corresponding to respective conductive contact regions. Thus, the process steps described herein for the fabrication of the conductive contact plugs may be carried out across the entire substrate 102 and for any number of semiconductor device structures on substrate 102.

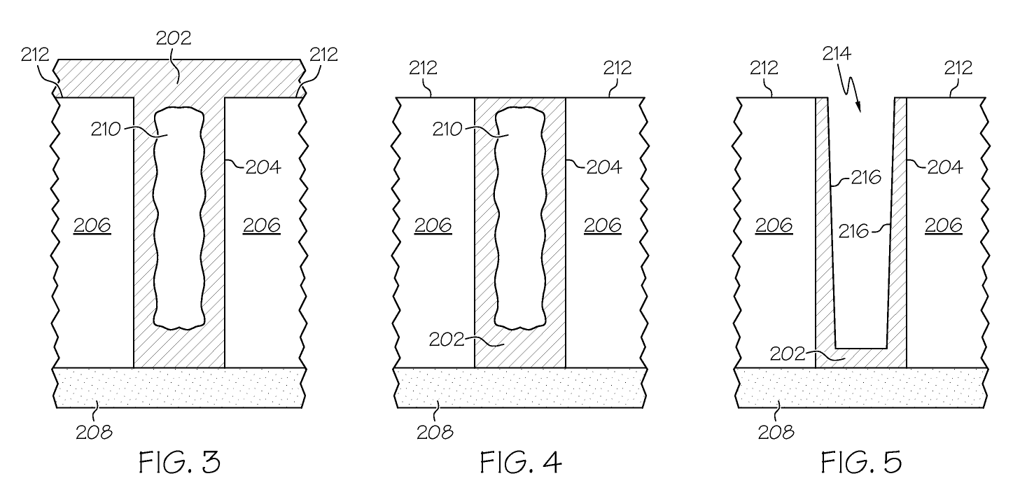

FIGS. 3-7 are cross sectional views that illustrate the formation of an exemplary conductive contact plug in accordance with one preferred process. For the sake of simplicity, only one conductive contact plug is shown in each of FIGS. 3-7. Although other fabrication steps or sub-processes may be performed after the step in the process depicted in FIG. 2 (e.g., the formation of very thin titanium and/or nitride barrier liners in vias 114), this example continues by depositing an electrically conductive material 202 on the semiconductor device structure (FIG. 3). FIG. 3 is a detail section that shows a via 204 formed in an insulating material 206; via 204 terminates at a conductive contact region 208, as described above with reference to FIG. 1 and FIG. 2. For this embodiment, electrically conductive material 202 at least partially fills via 204. In other words, a seam, gap, pocket, or void 210 remains within via 204 after the deposition step. It should be noted that FIG. 3 depicts a “filled via” even though via 204 need not be completely filled with the electrically conductive material 202.

The electrically conductive material 202 will typically be a metal material. In preferred embodiments, electrically conductive material 202 includes tungsten or an alloy thereof. Alternatively, electrically conductive material 202 may include, without limitation, copper or an alloy thereof. Electrically conductive material 202 is preferably deposited using a conformal deposition technique, such as an appropriate chemical vapor deposition (CVD) technique.

During the deposition step, some amount of electrically conductive material 202 may be deposited over the layer of insulating material 206. FIG. 3 illustrates how this excess material (referred to as “overburden”) overlies the upper surface 212 of insulating material 206. Although other fabrication steps or sub-processes may be performed after the step in the process depicted in FIG. 3, this example continues by removing at least some of the overburden portion of electrically conductive material 202. Preferably, all of the overburden portion is removed from the semiconductor device structure, as depicted in FIG. 4. Although not shown in FIG. 4, the removal of the overburden portion may cause the void 210 to become opened near the upper surface 212 of insulating material 206. In other words, rather than remaining encased within insulating material 206 (as shown in FIG. 4), the void 210 may take the form of an accessible cavity or recess.

In certain embodiments, the overburden portion of electrically conductive material 202 is removed by polishing the electrically conductive material 202 off the layer of insulating material 206. In this regard, the overburden portion can be removed by chemical mechanical polishing/planarizing (CMP), using the layer of insulating material 206 as an endpoint measure. In other embodiments, the overburden portion of electrically conductive material 202 is removed by etching the electrically conductive material 202 away from the layer of insulating material 206. This etching step may employ an appropriate anisotropic etchant chemistry and technique that selectively etches the electrically conductive material 202. For example, the overburden portion of electrically conductive material 202 can be etched by reactive ion etching (RIE) using a CHF₃, CF₄, or SF₆ chemistry. This etching step will be controlled as needed to ensure that the appropriate amount of the electrically conductive material 202 is removed. In practice, this etching step can be controlled by specifying the etch time, specifying the set of etching conditions, selecting a suitable etchant concentration, selecting an appropriate etchant chemistry, and/or adjusting other parameters and conditions that influence the etching process.

Although other fabrication steps or sub-processes may be performed after the step in the process depicted in FIG. 4, this example continues by anisotropically etching a portion of the electrically conductive material 202 located in the filled via. FIG. 5 depicts the condition of the device structure following this etching step. This etching step results in a lined via 214—via 204 becomes lined with the remaining electrically conductive material 202. This etching step may employ an appropriate anisotropic etchant chemistry and technique that selectively etches the electrically conductive material 202. In certain embodiments, this etching step employs RIE with a CHF₃, CF₄, or SF₆ chemistry. The formation of lined via 214 is controlled as needed to ensure that the appropriate amount of the electrically conductive material 202 is removed, and to obtain the desired profile and characteristics for lined via 214. In practice, this etching step can be controlled by specifying the etch time, specifying the set of etching conditions, selecting a suitable etchant concentration, selecting an appropriate etchant chemistry, and/or adjusting other parameters and conditions that influence the etching process.

As mentioned above with reference to FIG. 4, the overburden portion of electrically conductive material 202 could be removed by etching. In such an embodiment, the creation of lined via 214 may leverage the same etchant chemistry and/or the same etching procedure. For example, the same anisotropic etchant chemistry can be used to anisotropically etch the overburden portion of electrically conductive material 202, and to also anisotropically etch some of the electrically conductive material 202 located in the filled via. In certain embodiments, the removal of the overburden portion and the formation of lined via 214 may be associated with a single anisotropic etch procedure. In other embodiments, the etching conditions, the etchant chemistry, the etchant concentration, and/or other parameters may be changed after the overburden portion has been removed. In yet other embodiments, it may be possible to alter the etching conditions, the etchant chemistry, the etchant concentration, and/or other parameters while the etching step(s) are ongoing.

Referring again to FIG. 5, the etching of the electrically conductive material 202 is suitably controlled such that lined via 214 includes a tapered inner wall 216. In this regard, inner wall 216 tapers inwardly toward the bottom of via 204, and tapers outwardly toward the top of via 204 (where “top” and “bottom” refer to the arbitrary reference perspective of FIG. 5). The angle of this taper (which will be less than 90 degrees) is typically in the range of about 85-89 degrees, although the actual angle may vary from device to device. The tapering of inner wall 216 is desirable to promote better deposition of electrically conductive material within lined via 214 (described below), and to reduce the likelihood of subsequent formation of another void in the area above conductive contact region 208. As illustrated in FIG. 5, the etching of the electrically conductive material 202 eliminates (or substantially reduces) the irregular and “rough” surface of the void, and replaces that irregular surface with the relatively smooth inner wall 216.

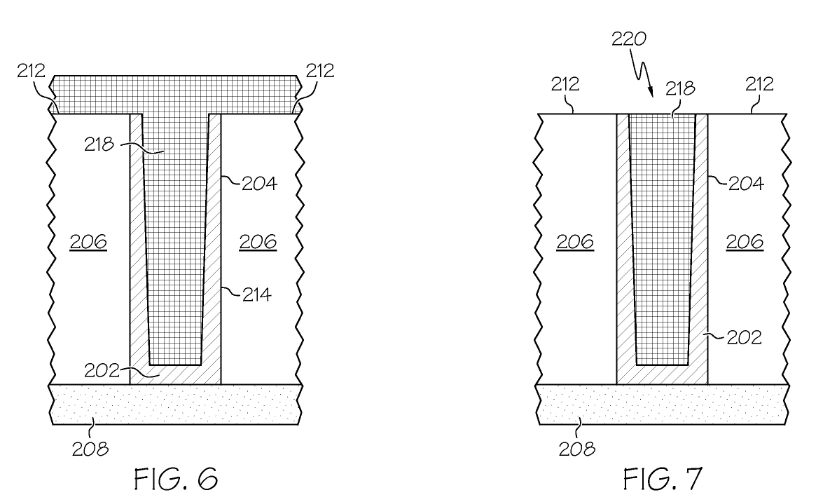

Although other fabrication steps or sub-processes may be performed after the step in the process depicted in FIG. 5, this example continues by depositing an electrically conductive material 218 on the semiconductor device structure (FIG. 6). Electrically conductive material 218 is deposited such that it at least partially fills lined via 214. For this embodiment, electrically conductive material 218 substantially fills or completely fills (as shown in FIG. 6) lined via 214. Notably, FIG. 6 illustrates how electrically conductive material 218 fills lined via 214 without creating any detectable voids, gaps, seams, or pockets. This filled characteristic is desirable to reduce the likelihood of trapping foreign particles during the subsequent CMP step described below.

The electrically conductive material 218 will typically be a metal material. In practice, electrically conductive material 218 is selected from the group of materials that includes, without limitation: tungsten; copper; silver; ruthenium; tantalum; and alloys thereof. In preferred embodiments, electrically conductive material 202 is a tungsten material, and electrically conductive material 218 is a copper material. Electrically conductive material 218 is preferably deposited using a conformal deposition technique, such as an appropriate atomic layer deposition (ALD) technique. In alternate embodiments, an appropriate CVD or physical vapor deposition (PVD) technique may be employed in lieu of ALD.

During this deposition step, some amount of electrically conductive material 218 may be deposited over the layer of insulating material 206. FIG. 6 illustrates how this excess overburden material overlies the upper surface 212 of insulating material 206. Although other fabrication steps or sub-processes may be performed after the step in the process depicted in FIG. 6, this example continues by removing at least some of the overburden portion of electrically conductive material 218. Preferably, all of the overburden portion is removed from the semiconductor device structure, as depicted in FIG. 7.

In certain embodiments, the overburden portion of electrically conductive material 218 is removed by polishing it off the layer of insulating material 206. In this regard, the overburden portion of electrically conductive material 218 can be removed by CMP, using the layer of insulating material 206 as an endpoint measure. The removal of this overburden material results in the formation of a conductive contact plug 220 for conductive contact region 208. Notably, conductive contact plug 220 substantially fills via 204 (in preferred embodiments, it completely fills via 204, as shown in FIG. 7). In other words, the fabrication technique described above results in conductive contact plug 220 having no measurable or detectable voids, gaps, keyholes, or pockets formed therein. The illustrated embodiment of conductive contact plug 220 is composed of two sections or elements: the outer section formed from electrically conductive material 202; and the inner section formed from electrically conductive material 218. Little or no discontinuities exist at the junction between these two sections, which is desirable to reduce the resistance of conductive contact plug 220.

FIGS. 8-13 are cross sectional views that illustrate the formation of an exemplary conductive contact plug in accordance with an alternate process. For the sake of simplicity, only one conductive contact plug is shown in each of FIGS. 8-13. Moreover, some of the process steps, materials, and aspects of this alternate process are similar or identical to that described above for the formation of conductive contact plug 220. These common steps, materials, and aspects will not be redundantly described in the context of the embodiment illustrated in FIGS. 8-13.

The alternate process depicted in FIGS. 8-13 may be carried out after the semiconductor device structure shown in FIG. 2 has been provided. Although other fabrication steps or sub-processes may be performed after the step in the process depicted in FIG. 2 (e.g., the formation of thin titanium and/or nitride barrier liners in vias 214), this example continues by depositing a metal material 302 on the semiconductor device structure and in via 204 (FIG. 8). The deposition of metal material 302 is controlled in an appropriate manner such that metal material 302 only partially fills via 204, forming a partially filled via 304. In this regard, the goal of this deposition step is to not completely fill via 204. Rather, this deposition step is intended to only line via 204 with an amount of metal material 302. As shown in FIG. 8, this deposition step results in a cavity 306 within via 204, and cavity 306 need not be completely enclosed within metal material 302. Indeed, the illustrated embodiment includes an accessible opening 305 formed near the top of via 204.

In preferred embodiments, metal material 302 is a tungsten material, although other metals (such as copper) may also be used. Metal material 302 is preferably deposited using a conformal deposition technique, such as an appropriate CVD technique with or without any nucleation step, including ALD, PNL, and any alloy nucleation type such as WN. During this deposition step, some amount of metal material 302 may be deposited over the layer of insulating material 206. However, this excess overburden material need not be removed before the next process step.

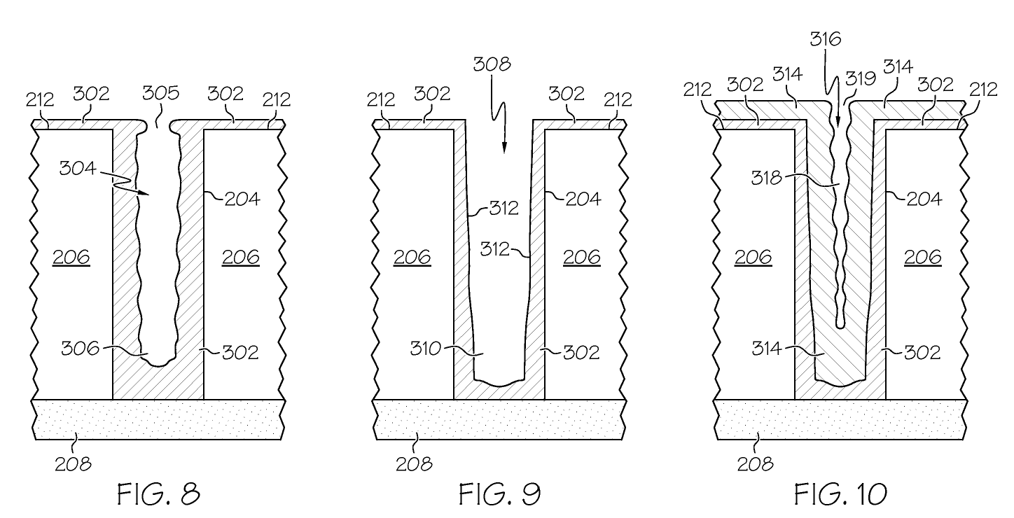

Although other fabrication steps or sub-processes may be performed after the step in the process depicted in FIG. 8, this example continues by anisotropically etching a portion of the metal material 302 that is located in the partially filled via 304. FIG. 9 depicts the condition of the device structure following this etching step. This etching step results in a lined via 308, i.e., via 204 becomes lined with the remaining metal material 302. This etching step may employ an appropriate anisotropic etchant chemistry and technique, such as RIE with a CHF₃, CF₄, or SF₆ chemistry. Notably, this etching step employs an etchant that selectively attacks the metal material 302. The formation of lined via 308 is controlled as needed to ensure that the appropriate amount of the metal material 302 is removed, and to obtain the desired profile and characteristics for lined via 308. The etching of the metal material 302 is suitably controlled such that lined via 308 includes an accessible pocket 310 that is defined by the remaining metal material 302. In certain embodiments, the etching of metal material 302 results in a tapered inner wall 312, as described above with reference to FIG. 5. The tapering of inner wall 312 is desirable to promote better deposition of additional metal material in lined via 308.

Although other fabrication steps or sub-processes may be performed after the step in the process depicted in FIG. 9, this example continues by depositing a metal material 314 on the semiconductor device structure and in lined via 308 (FIG. 10). Metal material 314 is deposited such that it at least partially fills lined via 308, resulting in a subsequently filled via 316. In the illustrated embodiment, metal material 314 does not completely fill lined via 308. In other words, a cavity 318 remains in via 204 after this second deposition step. Cavity 318 need not be completely enclosed within metal material 314. Indeed, the illustrated embodiment includes an accessible opening 319 formed near the top of via 204. In alternate embodiments, the second deposition step may substantially fill or completely fill lined via 308. In such embodiments, the next major step in the process flow may be the removal of overburden material (as described below with reference to FIG. 13).

In preferred embodiments, metal material 314 and metal material 302 are the same, similar, or compatible materials. For example, metal material 302 and metal material 314 can both be tungsten, although other metals (such as copper) may also be used. Metal material 314 is preferably deposited using a conformal deposition technique, such as an appropriate CVD technique. During this second deposition step, some amount of metal material 314 may be deposited overlying the layer of insulating material 206 and/or overlying the overburden portion of metal material 302. As depicted in FIG. 10, the overburden material may accumulate on the layer of insulating material 206 because the process need not include any intermediate polishing or planarizing steps.

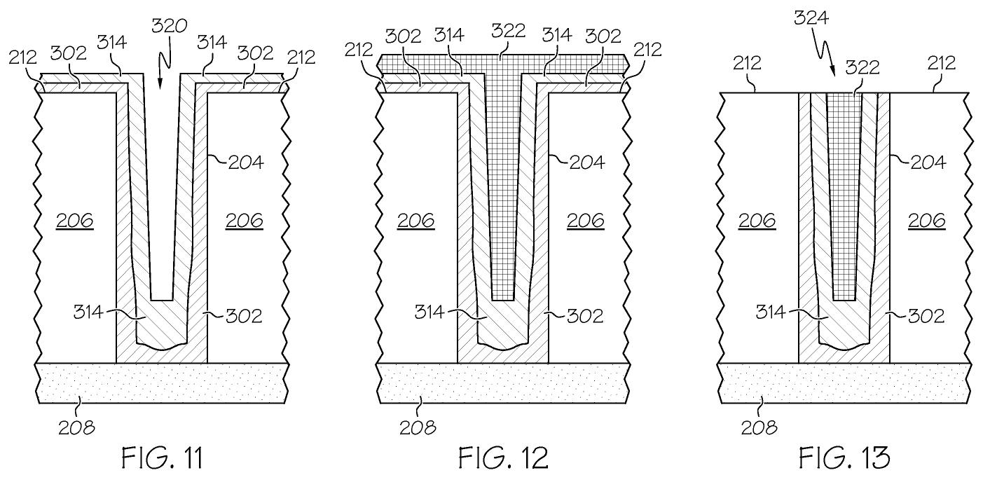

Although other fabrication steps or sub-processes may be performed after the step in the process depicted in FIG. 10, this example continues by anisotropically etching a portion of the metal material 314 that is located in the subsequently filled via 316. FIG. 11 depicts the condition of the device structure following this etching step. In practice, this second etching step may be similar to the first etching step described above with reference to FIG. 9. This second etching step results in a double lined via 320, i.e., via 204 includes a first liner composed of metal material 302 and a second liner composed of metal material 314, where the second liner covers the first liner.

Although other fabrication steps or sub-processes may be performed after the step in the process depicted in FIG. 11, this example continues by depositing a metal material 322 on the semiconductor device structure and in double lined via 320 (FIG. 12). Metal material 322 is deposited such that it at least partially fills double lined via 320. In the illustrated embodiment, metal material 322 substantially fills the double lined via 322 (more specifically, FIG. 12 depicts metal material 322 completely filled in the double lined via 322). In preferred embodiments, metal material 322, metal material 314, and metal material 302 are the same, similar, or compatible materials. For example, tungsten can be used for metal materials 302/314/322. Metal material 322 is preferably deposited using an appropriate CVD technique, as mentioned previously. During this third deposition step, some amount of metal material 322 may be deposited overlying the layer of insulating material 206, the overburden portion of metal material 302, and the overburden portion of metal material 314.

It should be appreciated that additional etching and metal deposition steps (as described above) can be carried out if necessary to continue adding liners in via 204 and to continue filling via 204 with the desired metal material. Thus, if the metal material does not substantially or completely fill via 204, the process may continue with another iteration of the etching and metal deposition steps. On the other hand, if the metal material substantially or completely fills via 204 after completion of any deposition step, then the process can proceed with the removal of the overburden areas. FIG. 12 illustrates how this excess overburden material overlies the upper surface 212 of insulating material 206. Although other fabrication steps or sub-processes may be performed after the step in the process depicted in FIG. 12, this example continues by removing at least some of the overburden areas of metal material 302, 314, and 322. Preferably, all of the overburden material is removed from the semiconductor device structure, as depicted in FIG. 13.

In certain embodiments, the overburden material is removed by polishing it off the layer of insulating material 206. In this regard, the overburden material can be removed by CMP, using the layer of insulating material 206 as an endpoint measure. The removal of this overburden material results in the formation of a conductive contact plug 324 for conductive contact region 208. Notably, conductive contact plug 324 substantially fills via 204 (preferably, it completely fills via 204, as shown in FIG. 13). In other words, the fabrication technique described above results in conductive contact plug 324 having no measurable or detectable voids, gaps, keyholes, or pockets formed therein. The illustrated embodiment of conductive contact plug 324 is composed of three sections or elements: the outer section formed from metal material 302; the intermediate section formed from metal material 314; and the inner section formed from metal material 322. Little or no discontinuities exist at the junctions between these three sections, which is desirable to reduce the resistance of conductive contact plug 324.

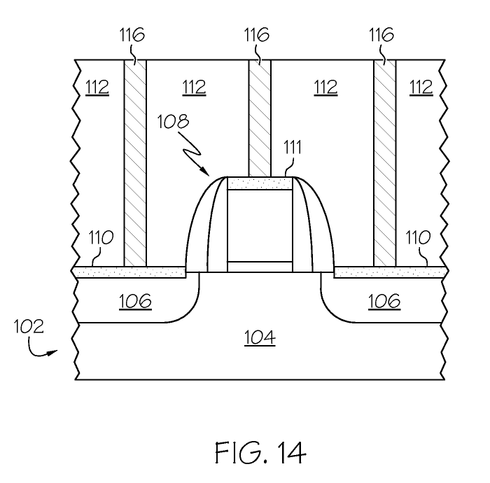

Referring back to FIG. 2, semiconductor device structure 100 may utilize contact plugs formed in accordance with the process described above for conductive contact plug 220 (FIG. 7), or formed in accordance with the process described above for conductive contact plug 324 (FIG. 13). In this regard, FIG. 14 is a cross sectional view of semiconductor device structure 100, after formation of conductive contact plugs 1 16. Conductive contact plugs 116 are formed in the layer of insulating material 112 such that each conductive contact plug 116 terminates (at one end) at its respective conductive contact region 110/111.

As explained above, each conductive contact plug 116 may include an etched liner formed from a first electrically conductive material (e.g., tungsten), and a second electrically conductive material (e.g., copper) deposited in the etched liner. In certain embodiments, the etched liner is formed by CVD and subsequent anisotropic etching of tungsten, and the second material is formed by ALD. In alternate embodiments, each conductive contact plug 116 may be formed by repeated CVD and subsequent anisotropic etching of an appropriate metal material, such as tungsten. The repeated deposition and etching of tungsten can be controlled to avoid formation of seams, gaps, or voids in the tungsten plug.

After conductive contact plugs 116 have been created, any number of known backend process steps can be performed to complete the fabrication of the semiconductor device. For example, conductive metal traces/lines can be formed as needed to establish electrical contact with conductive contact plugs 116. Such conductive metal traces/lines are typically formed in the Metal-1 (M1) layer of the semiconductor device. Other process steps may also be carried out to prepare the semiconductor device for delivery.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method of forming conductive contact plugs for a semiconductor device, the method comprising:
providing a semiconductor device structure having a conductive contact region, a layer of insulating material overlying the conductive contact region, and a via formed in the layer of insulating material and terminating at the conductive contact region;
depositing a first electrically conductive material on the semiconductor device structure such that the first electrically conductive material at least partially fills the via, resulting in a filled via;
anisotropically etching a portion of the first electrically conductive material located in the filled via, resulting in a lined via; and
thereafter depositing a second electrically conductive material on the semiconductor device structure such that the second electrically conductive material at least partially fills the lined via.

2. The method of claim 1, wherein depositing the first electrically conductive material comprises chemical vapor deposition of metal.

3. The method of claim 2, wherein the metal subject to chemical vapor deposition is selected from the group consisting of: tungsten, copper, and alloys thereof.

4. The method of claim 2, wherein depositing the second electrically conductive material comprises atomic layer deposition of metal.

5. The method of claim 4, wherein the metal subject to atomic layer deposition is selected from the group consisting of: tungsten, copper, silver, ruthenium, tantalum, and alloys thereof.

6. The method of claim 2, wherein depositing the second electrically conductive material comprises chemical vapor deposition of metal.

7. The method of claim 1, wherein anisotropically etching comprises selective reactive ion etching of the first electrically conductive material.

8. The method of claim 1, wherein:
depositing the first electrically conductive material comprises depositing the first electrically conductive material overlying the layer of insulating material; and
the method further comprises removing, prior to the anisotropically etching step, at least some of the first electrically conductive material overlying the layer of insulating material.

9. The method of claim 8, wherein removing at least some of the first electrically conductive material comprises polishing the first electrically conductive material off the layer of insulating material.

10. The method of claim 8, wherein removing at least some of the first electrically conductive material comprises etching the first electrically conductive material away from the layer of insulating material.

11. The method of claim 10, wherein:
etching the first electrically conductive material off the layer of insulating material comprises etching the first electrically conductive material using an anisotropic etchant chemistry; and
anisotropically etching the portion of the first electrically conductive material located in the filled via comprises etching the portion of the first electrically conductive material using the anisotropic etchant chemistry.

12. The method of claim 1, wherein:
depositing the second electrically conductive material comprises depositing the second electrically conductive material overlying the layer of insulating material; and
the method further comprises removing at least some of the second electrically conductive material overlying the layer of insulating material.

13. The method of claim 12, wherein removing at least some of the second electrically conductive material comprises polishing the second electrically conductive material off the layer of insulating material.

14. A method of forming conductive contact plugs for a semiconductor device, the method comprising:
providing a semiconductor device structure having a conductive contact region, a layer of insulating material overlying the conductive contact region, and a via formed in the layer of insulating material and terminating at the conductive contact region;
depositing a metal material in the via such that the metal material partially fills the via, resulting in a partially filled via;
anisotropically etching a portion of the metal material located in the partially filled via, resulting in a lined via;
thereafter depositing the metal material in the lined via such that the metal material at least partially fills the lined via, resulting in a subsequently filled via; and
if the metal material does not substantially fill the subsequently filled via, depositing more of the metal material in the subsequently filled via.

15. The method of claim 14, wherein, if the metal material substantially fills the subsequently filled via, removing overburden areas of the metal material overlying the layer of insulating material.

16. The method of claim 14, further comprising, after depositing more of the metal material, removing overburden areas of the metal material overlying the layer of insulating material.

17. The method of claim 14, wherein:
depositing the metal material in the via comprises chemical vapor deposition of tungsten; and
depositing the metal material in the lined via comprises chemical vapor deposition of tungsten.

18. The method of claim 14, wherein anisotropically etching comprises selective reactive ion etching of the metal material.

19. A semiconductor device comprising:
a semiconductor material;
a conductive contact region for the semiconductor material;
a layer of insulating material overlying the semiconductor material and the conductive contact region; and
a conductive contact plug formed in the layer of insulating material and terminating at the conductive contact region, the conductive contact plug comprising an etched liner formed from a first electrically conductive material, and comprising a second electrically conductive material deposited in the etched liner.

20. The semiconductor device of claim 19, wherein:
the etched liner is formed by chemical vapor deposition and subsequent anisotropic etching of a first metal material; and
the conductive contact plug is formed by atomic layer deposition of a second metal material.

21. The semiconductor device of claim 20, wherein:
the first metal material comprises tungsten; and
the second metal material is selected from the group consisting of: tungsten, copper, silver, ruthenium, tantalum, and alloys thereof.
